(19) United States
(12) Patent Application Publication
(10) Pub. No.: US 2024/0165765 A1
(43) Pub. Date: May 23, 2024

(54) METHOD FOR MANUFACTURING SEMICONDUCTOR WAFER

(71) Applicant: SHIN-ETSU HANDOTAI CO., LTD., Tokyo (JP)

(72) Inventor: Ryo HASEGAWA, Nishigo-mura (JP)

(73) Assignee: SHIN-ETSU HANDOTAI CO., LTD., Tokyo (JP)

(21) Appl. No.: 18/283,051

(22) PCT Filed: Mar. 3, 2022
(86) PCT No.: PCT/JP2022/009007

§ 371 Date: Sep. 20, 2023

(30) Foreign Application Priority Data
Apr. 12, 2021 (JP) 2021-067249

(51) Int. Cl. B24B 9/06; B24B 7/22; H01L 21/02

(52) U.S. Cl. CPC B24B 9/065; B24B 7/228; H01L 21/02021

(57) ABSTRACT

A method for manufacturing a semiconductor wafer, including: a chamfering step of grinding at least a periphery of a wafer to form a chamfered portion having a wafer edge portion and a wafer notch portion; a double-side polishing step; a mirror-surface chamfering step; and a mirror polishing step, wherein the mirror-surface chamfering step includes: a first mirror-surface chamfering process of polishing the wafer notch portion in the chamfered portion before the double-side polishing step; and a second mirror-surface chamfering process of polishing the wafer notch portion and the wafer edge portion after the double-side polishing step, and a polishing rate of the wafer notch portion in the second mirror-surface chamfering process is smaller than a polishing rate of the wafer notch portion in the first mirror-surface chamfering process.

### TECHNICAL FIELD

The present invention relates to a method for manufacturing a semiconductor wafer.

### BACKGROUND ART

A method for manufacturing a semiconductor wafer commonly comprises: a slicing step of cutting a single crystal ingot into a thin wafer; a chamfering step for preventing chipping and cracking of a periphery of the wafer; a wrapping step or a double-side grinding step for eliminating variation of a thickness of the wafer for planarization; an etching step for removing damage and contamination of the wafer introduced by the wrapping step or the double-side grinding step; a double-side polishing step of simultaneously polishing both of front and back major surfaces for obtaining highly precise planarization quality and nano-topography quality of the wafer; a mirror-surface chamfering step of forming a mirror surface from the chamfered portion; a mirror polishing step for forming a mirror surface from the major surface of the wafer; etc. in this order.

For the mirror-surface chamfering of the wafer periphery, a finer process has been required as a semiconductor device integration increasing. This step is needed for improving an yield of the semiconductor device by forming the mirror surface from the chamfered portion and improving the roughness to inhibit dust generation from the chamfered portion in the post-processes.

A wafer notch portion is polished in the mirror-surface chamfering step. The mirror-surface chamfering step has a purpose of forming a mirror surface from the wafer notch portion and a wafer edge portion, and the process conditions are regulated therefor. Roughness after the process depends on a type of a polishing cloth, a type of a polishing slurry, a process time, a number of rotation of the polishing cloth, and a pressing pressure of the polishing cloth.

In the mirror-surface chamfering step, conditions with a relatively large polishing rate are used for keeping productivity of a mirror-surface chamfering apparatus, which causes roughness deterioration. According to Patent Document 1, a larger load or larger polishing rate in the process more deteriorates the roughness after the process. Polishing a plurality of times and sequentially reducing the polishing rates improve the roughness.

In the mirror-surface chamfering step, the wafer notch portion and the wafer edge portion are commonly processed in the identical mirror-surface chamfering apparatus in any order with considering the productivity. Thus, setting a polishing time for the wafer notch portion much longer than a process time for polishing the wafer edge portion increases a residence time of the wafer in the mirror-surface chamfering apparatus, which deteriorates the productivity.

Therefore, the polishing time for the wafer notch portion is conventionally approximately same as the polishing time for the wafer edge portion, and process conditions having an excessively large polishing rate are needed to be used in order to achieve a sufficient polishing removal. Thus, sufficiently improved notch roughness has not been obtained.

### CITATION LIST

### Patent Literature

Patent Document 1: JP 3846706 B
Patent Document 2: JP 6825733 B
Patent Document 3: JP 2001-300837 A

### SUMMARY OF INVENTION

### Technical Problem

The present invention has been made to solve the above problem. An object of the present invention is to provide a method for manufacturing a semiconductor wafer that can inhibit the deterioration of the surface roughness of the wafer notch portion derived from the polishing rate of the wafer notch portion in the mirror-surface chamfering step in the semiconductor wafer manufacturing.

### Solution to Problem

To solve the above problem, the present invention provides a method for manufacturing a semiconductor wafer, comprising:
a chamfering step of grinding at least a periphery of a wafer having a wafer notch portion to form a chamfered portion having a wafer edge portion and the wafer notch portion;
a double-side polishing step of polishing both major surfaces of the wafer;
a mirror-surface chamfering step of polishing the chamfered portion to form a mirror surface; and
a mirror polishing step of mirror polishing at least one of both the major surfaces, wherein
the mirror-surface chamfering step comprises:
a first mirror-surface chamfering process of polishing the wafer notch portion in the chamfered portion before the double-side polishing step; and
a second mirror-surface chamfering process of polishing the wafer notch portion and the wafer edge portion after the double-side polishing step, and
a polishing rate of the wafer notch portion in the second mirror-surface chamfering process is smaller than a polishing rate of the wafer notch portion in the first mirror-surface chamfering process.

The inventive method for manufacturing a semiconductor wafer can inhibit the deterioration of the surface roughness of the wafer notch portion derived from the polishing rate of the wafer notch portion in the mirror-surface chamfering step in the semiconductor wafer manufacturing with keeping the productivity.

For example, the semiconductor wafer can be a silicon wafer.

The semiconductor wafer that can be manufactured by the inventive method for manufacturing a semiconductor wafer is not particularly limited, and for example, a silicon wafer can be manufactured.

In polishing the wafer notch portion in the first and second mirror-surface chamfering processes, the polishing is preferably performed by inserting a circular polishing cloth into the wafer notch portion perpendicular to a wafer surface.

Such a method can certainly polish the wafer notch portion in the mirror-surface chamfering step, and can achieve desired shape, surface state, and roughness.

An end surface of the wafer notch portion preferably has:
a first slope continued from one major surface of the wafer and inclined from the one major surface;
a second slope continued form the other major surface of the wafer and included from the other major surface; and
an end portion constituting an outermost periphery of the wafer, and
in the second mirror-surface chamfering process, all of the first slope, the second slope, and the end portion of the end surface of the wafer notch portion are preferably polished.

Such a method can more certainly polish the wafer notch portion in the mirror-surface chamfering step, and can achieve desired shape, surface state, and roughness.

### Advantageous Effects of Invention

As noted above, the inventive method for manufacturing a semiconductor wafer can achieve a sufficient polishing removal with keeping the productivity, by performing the mirror-surface chamfering processes before and after the double-side polishing step of the major surface and by reducing the polishing rate in the second mirror-surface chamfering, which is after the double-side polishing step, in the semiconductor wafer manufacturing, and can inhibit the deterioration of the surface roughness of the wafer notch portion derived from the large polishing rate. Therefore, the semiconductor wafer having excellent surface roughness of the wafer notch portion can be manufactured.

### BRIEF DESCRIPTION OF DRAWINGS

FIG. 1 is a schematic plane view illustrating an example of a semiconductor wafer that can be manufactured by the inventive method for manufacturing a semiconductor wafer.

FIG. 2 is a flowchart showing an example of the inventive method for manufacturing a semiconductor wafer.

FIG. 3 is an outline schematic view describing a wafer notch shape after a chamfering step.

FIG. 4 is a sectional view illustrating an example of a wafer notch portion after the chamfering step.

FIG. 5 is a graph indicating surface roughness of wafer notch portions of semiconductor wafers obtained in Example and Comparative Examples.

### DESCRIPTION OF EMBODIMENTS

As noted above, the mirror surfaces are formed from the wafer notch portion and the wafer edge portion in the mirror-surface chamfering step, and the process conditions are regulated therefor. The roughness after the process depends on a type of a polishing cloth, a type of a polishing slurry, a process time, a number of rotation of the polishing cloth, and a pressing pressure of the polishing cloth.

The original purpose of the mirror-surface chamfering step is to remove scars, etc. in the chamfered portion to improve the roughness. A certain amount or more of the polishing removal is required in order to remove the scars, etc., and a larger polishing removal more reduces the scars after the process. Accordingly, the mirror-surface chamfering process under conditions of a large polishing rate can yield an effect of removing the scars, etc. in a shorter time. However, the process with a large polishing rate may deteriorate the roughness, as noted above, and it is difficult to achieve both of removal of the scars and sufficient improvement of the roughness by the conventional method for manufacturing a semiconductor wafer.

That is, in the mirror-surface chamfering step, the polishing rate of the wafer notch portion may deteriorate the surface roughness of the wafer notch portion, and therefore, a method for manufacturing a wafer that can solve these problems has been required.

The present inventors have been made earnest study to achieve the above purpose. As a result, the present inventors have found that the above problem can be solved by, under conditions of performing mirror-surface chamfering processes before and after a double-side polishing step, setting a polishing rate of a wafer notch portion in a second mirror-surface chamfering process, which is performed after the double-side polishing step, to be smaller than a polishing rate of the wafer notch portion in a first mirror-surface chamfering process, which is performed before the double-side polishing step. This finding has led to complete the inventive method for manufacturing a wafer.

Specifically, the present invention is a method for manufacturing a semiconductor wafer, comprising:
a chamfering step of grinding at least a periphery of a wafer having a wafer notch portion to form a chamfered portion having a wafer edge portion and the wafer notch portion;
a double-side polishing step of polishing both major surfaces of the wafer;
a mirror-surface chamfering step of polishing the chamfered portion to form a mirror surface; and
a mirror polishing step of mirror polishing at least one of both the major surfaces, wherein
the mirror-surface chamfering step comprises:
a first mirror-surface chamfering process of polishing the wafer notch portion in the chamfered portion before the double-side polishing step; and
a second mirror-surface chamfering process of polishing the wafer notch portion and the wafer edge portion after the double-side polishing step, and
a polishing rate of the wafer notch portion in the second mirror-surface chamfering process is smaller than a polishing rate of the wafer notch portion in the first mirror-surface chamfering process.

Patent Documents 1 and 2 disclose the art for polishing a chamfered portion in a wafer. Patent Document 3 discloses the art about a method for polishing a notch portion in a wafer and an apparatus therefor. However, none of the Patent Documents 1 to 3 describes nor suggest that in a method where mirror-surface processes of the chamfered portion in the wafer are performed before and after the double-side polishing step for both the major surfaces of the wafer, the polishing rate of the wafer notch portion in the mirror-surface chamfering process performed after the double-side polishing step is set to be smaller than the polishing rate of the wafer notch portion in the mirror-surface chamfering process performed before the double-side polishing step.

Hereinafter, the present invention will be described in detail with reference to the drawings, but the present invention is not limited thereto.

### [Semiconductor Wafer]

First, an example of a semiconductor wafer that can be manufactured by the inventive method for manufacturing a semiconductor wafer will be described.

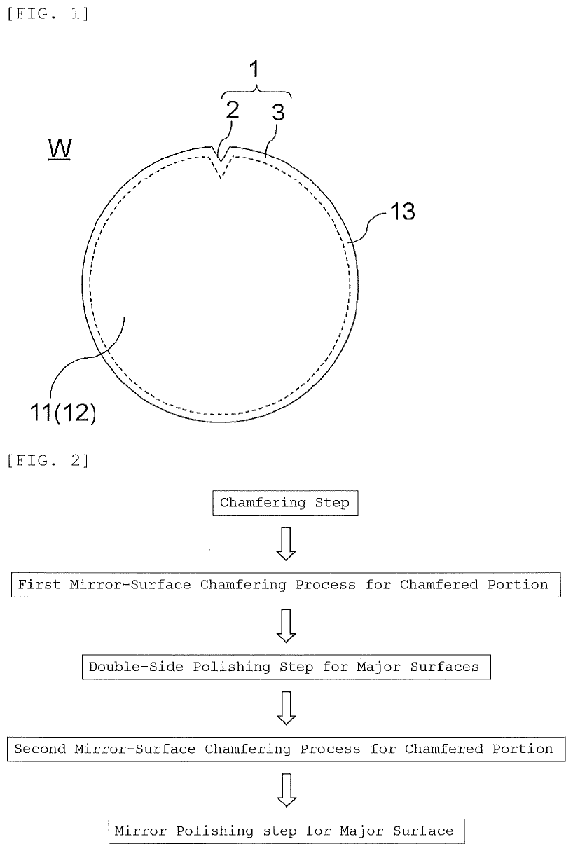

FIG. 1 is a schematic plane view illustrating an example of the semiconductor wafer that can be manufactured by the inventive method for manufacturing a semiconductor wafer.

A semiconductor wafer W illustrated in FIG. 1 has a first major surface 11, which is a mirror surface, and a second major surface 12 on a back side thereof. On a periphery 13 of the semiconductor wafer W, a chamfered portion 1 is formed. The chamfered portion 1 has a wafer edge portion 3 formed along the periphery 13 and a wafer notch portion 2 formed on a part of the wafer edge portion 3.

### Method for Manufacturing Semiconductor Wafer

Next, the inventive method for manufacturing a semiconductor wafer will be described with examples with reference to FIG. 2. Hereinafter, the description will be made with reference again to the semiconductor wafer illustrated in FIG. 1.

FIG. 2 is a flowchart showing an example of the inventive method for manufacturing a semiconductor wafer.

The method for manufacturing a semiconductor wafer in this example includes: a chamfering step of grinding a periphery 13 of a wafer 1 having a wafer notch portion 2 to form a chamfered portion 1 having a wafer edge portion 3 and the wafer notch portion 2; a first mirror-surface chamfering process of polishing the wafer notch portion 2 in the chamfered portion 1; a double-side polishing step of polishing both major surfaces 11 and 12 of the wafer; a second mirror-surface chamfering process of polishing the wafer notch portion 2 and the wafer edge portion 3; and a mirror polishing step of mirror polishing at least one of both the major surfaces 11 and 12. That is, the first mirror-surface chamfering process of polishing the wafer notch portion 2 in the chamfered portion 1 is performed before the double-side polishing step for both the major surfaces 11 and 12, and the second mirror-surface chamfering process of polishing both of the wafer notch portion 2 and the wafer edge portion 3 in the chamfered portion 1 is performed after the double-side polishing step for both the major surfaces 11 and 12. A polishing rate of the wafer notch portion 2 in the second mirror-surface chamfering process for the chamfered portion is smaller than a polishing rate of the wafer notch portion 2 in the first mirror-surface chamfering process. The first and second mirror-surface chamfering processes are included in the mirror-surface chamfering step of polishing the chamfered portion to form a mirror surface.

Such a method for manufacturing a semiconductor wafer can finally yield a sufficient polishing removal for the wafer notch portion 2 even with reducing the polishing rate in the second mirror-surface chamfering process when a sufficient polishing removal of the wafer notch portion 2 can be obtained in the first mirror-surface chamfering process before the double-side polishing step. Therefore, the polishing rate of the wafer notch portion 2 in the second mirror-surface chamfering process can be reduced.

Furthermore, the surface roughness of the wafer notch portion 2 can be improved by setting the polishing rate of the wafer notch portion 2 in the second mirror-surface chamfering to be smaller than the polishing rate of the wafer notch portion 2 in the first mirror-surface chamfering process.

In the first mirror-surface chamfering process, a process time in the process, a number of rotation of a polishing cloth, and a pressing pressure can be freely set, and larger values thereof yield a larger polishing removal and a larger effect of removing scars, etc.

In the second mirror-surface chamfering process, a process time in the process, a number of rotation of a polishing cloth, and a pressing pressure can also be freely set, but larger values thereof more deteriorate the surface roughness after the process. Therefore, it is desired that these values are reduced in the second mirror-surface chamfering process. By setting these conditions in the second mirror-surface chamfering process to be smaller than the conditions in the first mirror-surface chamfering process, the polishing rate of the wafer notch portion 2 in the second mirror-surface chamfering process can be set to be smaller than the polishing rate in the first mirror-surface chamfering process. The polishing rate of the wafer notch portion 2 in the second mirror-surface chamfering process is preferably reduced such that the deterioration of the productivity due to the process requiring a time can be prevented.

The process conditions set in the first mirror-surface chamfering process and the second mirror-surface chamfering process, which are needed to be set so that the polishing rate of the wafer notch portion 2 in the second mirror-surface chamfering process is smaller than that in the first mirror-surface chamfering process, may be each set to any conditions. This is because the purpose of the first mirror-surface chamfering process is to remove surface scars, etc., and meanwhile, the purpose of the second mirror-surface chamfering process is to improve the roughness from that immediately after the first mirror-surface chamfering process. As long as these purposes are achieved, each of the process conditions can be arbitrary.

Each of the first mirror-surface chamfering process and the second mirror-surface chamfering process may be performed once, or may be performed with a plurality of stages.

The wafer notch portion 2 can be certainly polished to provide desired shape, surface state, and roughness by the following specific method for polishing the wafer notch portion 2. In the first mirror-surface chamfering process of the method, the wafer W is placed perpendicular to a polishing surface of the circular polishing cloth, and then the polishing cloth is inserted into the deepest portion of the notch and traverses the surface direction of the wafer W to perform the polishing. In the second mirror-surface chamfering process of this method, the polishing is performed with the same mechanism under process conditions of a polishing rate smaller than those in the first mirror-surface chamfering process.

The present invention can be particularly suitably used for a method for manufacturing a wafer in which the wafer edge portion 13 is mirror-surface chamfered before and after the double-side polishing step of the major surfaces 11 and 12. Polishing the wafer notch portion 2 and the wafer edge portion 3 in the first mirror-surface chamfering process can remove adhering foreign matters to inhibit generation of a scar in the double-side polishing step. In addition, such polishing can remove scars in the wafer edge portion 13, which are generated by contacting with an inner wall of a carrier hole generated in the double-side polishing step, in the second mirror-surface chamfering process. The present invention can be particularly efficiently used in this process in terms of the productivity. The present invention can yield both of improvement of the yield and the effect of improving the surface roughness on the wafer notch portion 2.

The inventive method for manufacturing a wafer can be particularly suitably used in a method for manufacturing a single crystal silicon wafer obtained from a single crystal silicon ingot.

Hereinafter, the present invention will be described in more detail with showing specific examples with reference to the drawings. The following description will be made with reference again to FIG. 1 and FIG. 2.

In an example, a single crystal ingot is firstly sliced to obtain a sliced wafer W having the wafer notch portion 2. Usable as the single crystal ingot in this case is a single crystal silicon ingot in which a groove to be the wafer notch portion later is formed on its periphery. The inventive method for manufacturing a wafer can be particularly suitably used in a method for manufacturing a semiconductor wafer, specifically a single crystal silicon wafer obtained from a single crystal silicon ingot.

Then, a chamfering process (chamfering step) in which the periphery of the wafer obtained in the above step is grinded to form a chamfered portion 1 having the wafer edge portion 3 and the wafer notch portion 2 is performed. For the chamfering step, any of commonly performed steps can be applied, and not particularly limited.

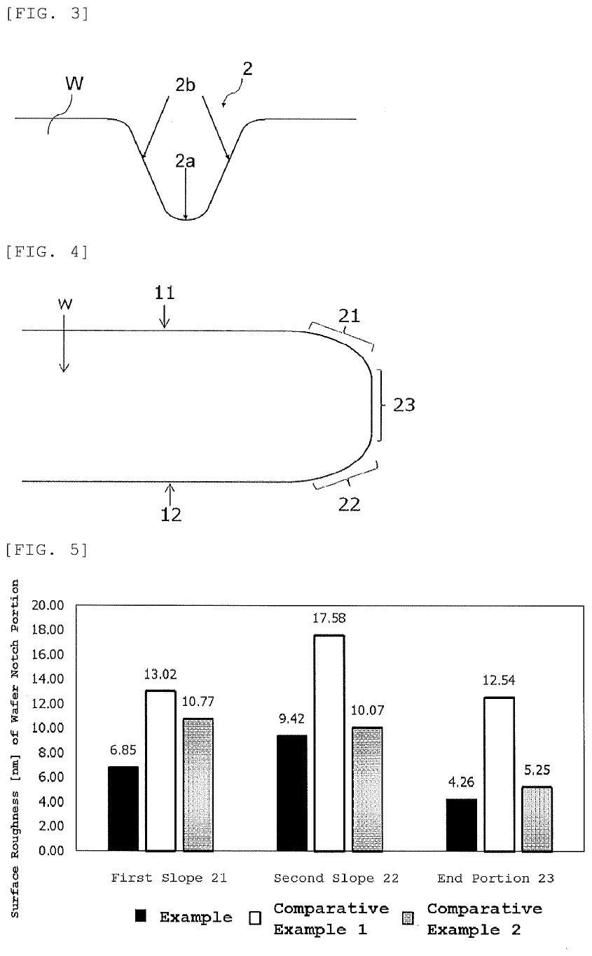

Here, a shape of the wafer notch portion after the chamfering process will be described with reference to FIG. 3 and FIG. 4. FIG. 3 illustrates the periphery of the wafer notch portion 2 viewed from the major surface 11 direction of the wafer W. The wafer notch portion 2 can be roughly divided into a bottom 2a and a straight portion 2b. Here, the notch bottom 2a is a portion of the deepest position of the wafer notch portion 2 with a curved contour, and each of the notch straight portions 2b is positioned on each of both ends of the bottom with a straight contour. FIG. 4 illustrates a sectional view of the end surface of the wafer notch portion 2 in a thickness direction of the wafer. Here, the end surface corresponds to a portion positioned on the outermost periphery of the wafer W and approximately perpendicular to the major surfaces 11 and 12 of the wafer W. The cross-sectional shape has a first slope 21 continued from the first major surface 11, which is one major surface of the wafer, and inclined from the first major surface 11. This chamfered cross-sectional shape also has a second slope 22 continued from the second major surface 12, which is the other major surface of the wafer W, and inclined from the second major surface 12. Furthermore, the cross-sectional shape has an end portion 23 constituting the outermost peripheral end portion of the wafer W. The end portion 23 conventionally has a slight slope. These cross-sectional shapes are common with the bottom 2a and straight line portion 2b in the wafer notch portion 2 and the wafer edge portion 3 illustrated in FIG. 1.

After the chamfering step is performed as described above, the major surfaces 11 and 12 of this wafer W can be subjected to a wrapping or double-side grinding process. For the wrapping and double-side grinding processes, any of commonly performed steps can be applied, and not particularly limited.

Then, to remove mechanical damage generated by the processes such as the chamfering and the wrapping, the wafer W processed as described above can be subjected to an etching process. For the etching process, any of commonly performed steps can be applied, and not particularly limited.

Then, in the present invention, a first mirror-surface chamfering process is performed in order to achieve a sufficient polishing removal of the wafer notch portion 2. It is desirable that the chamfered portion be subjected to mirror-surface polishing while contacting a circular polishing cloth with at least the bottom 2a and straight portion 2b of the wafer notch portion 2.

In such a first mirror-surface chamfering process, used is a mechanism such that the circular polishing cloth is inserted into the wafer notch portion 2 with an angle perpendicular to the major surfaces 11 and 12 of the wafer W, for example. The circular polishing cloth having predetermined number of rotation and rotating direction is inserted into the wafer notch portion 2 with supplying a polishing slurry, and pressed against the bottom 2a in the wafer notch portion 2 to perform the polishing. In the process, the circular polishing cloth traverses the surface of the major surfaces 11 and 12 of the wafer W in the left and right directions to also sufficiently polish the straight portion 2b in the wafer notch portion 2. Furthermore, in the process, inclining the wafer W with a predetermined angle enables to sufficiently polish all of the first and second slopes 21 and 22 and the end portion 23, which are illustrated in FIG. 4. The polishing rate of the wafer notch portion 2 in the first mirror-surface chamfering process can be, for example, 0.20 μm/sec or more and 0.30 μm/sec or less.

In the first mirror-surface chamfering process, surface-polishing the wafer edge portion 3 is optional, which may or may not be performed.

After the first mirror-surface chamfering process, a double-side polishing step of polishing both the major surfaces 11 and 12 of the wafer W is performed. For the double-side polishing step, any of commonly performed steps can be applied, and not particularly limited.

After the double-side polishing step, a second mirror-surface chamfering process is performed for a purpose of improving the surface roughness of the wafer notch portion 2 and forming a mirror surface from the wafer edge portion 3. Although the second mirror-surface chamfering process can be performed by using the same mechanism as in the first mirror-surface chamfering process, the polishing rate of the wafer notch portion 2 is set to be smaller than the polishing rate of the wafer notch portion 2 in the first mirror-surface chamfering process. For example, all of the process time, the number of rotation of a polishing cloth, and the pressing pressure against the wafer are set to be smaller than those in the conditions of the first mirror-surface chamfering process. This can reduce a load in the process and the polishing rate. The polishing rate of the wafer notch portion 2 in the second mirror-surface chamfering process can be, for example, 0.10 μm/sec or more and 0.18 μm/sec or less. For the mirror-surface chamfering process for the wafer edge portion 3, the same conditions as conventional conditions can be used.

In this second mirror-surface chamfering process, all of the first slope 21, the second slope 22, and the end portion 23 in the end surface of the wafer notch portion, which are, for example, illustrated in FIG. 4, are preferably polished.

Such a method can more certainly polish the wafer notch portion 2 in the mirror-surface chamfering step, and can provide desired shape, surface state, and roughness.

The mirror-surface chamfering step in the inventive method for manufacturing a semiconductor wafer comprises the first and second mirror-surface chamfering processes that have been described above.

Finally, the mirror polishing step in which at least one of the major surfaces 11 and 12 of the wafer W is mirror-surface polished is performed. This step is performed by a common technique.

With the steps as above, the wafer W to be a product is manufactured. Such a method for manufacturing the wafer W can achieve a sufficient polishing removal in the mirror-surface chamfering step with keeping the productivity, and can yield the effect of improving the surface roughness of the notch portion derived from the small polishing rate, which can produce a wafer with higher quality.

In the present invention, the process is performed in the above chamfering step with considering an amount of change in shape in the mirror-surface chamfering step. The present invention may include steps other than the above steps. For example, a washing step, a heat-treating step, etc. may be performed by a common method before or after each of the above steps as necessary.

### EXAMPLE

Hereinafter, the present invention will be specifically described by using Example and Comparative Examples, but the present invention is not limited thereto.

### Example

A wafer having a wafer notch portion was obtained by sequentially performing each process of slicing, a chamfering step, wrapping, and etching. This wafer was subjected to a first mirror-surface chamfering process. In the chamfering step, a chamfered portion having a wafer edge portion and the wafer notch portion was formed, and the wafer notch portion had a shape schematically illustrated in FIG. 3 and FIG. 4. In the first mirror-surface chamfering process, only the wafer notch portion was polished with two stages of a first stage and a second stage under conditions for achieving an amount of removal that was able to sufficiently remove scars, etc. Specifically, the first mirror-surface chamfering process was performed under the following conditions shown in the Table 1.

After the first mirror-surface chamfering process, double-side polishing in which both major surfaces of the wafer were polished was performed. Specifically, the double-side polishing was performed under the following conditions shown in Table 2.

Subsequently, a second mirror-surface chamfering process was performed. The second mirror-surface chamfering process had a purpose of improving roughness of the wafer notch portion from that immediately after the first mirror-surface chamfering process, and the wafer notch portion was processed with two stages of a first stage and a second stage with a small polishing rate and a small load. Specifically, the first and second slopes 21 and 22 and the end portion 23 illustrated in FIG. 4, which were in the bottom 2a and straight line 2b in the wafer notch portion 2 illustrated in FIG. 3, were polished in the same manner as in the first mirror-surface chamfering process by using the same mechanism as the first mirror-surface chamfering process. All of a process time, a number of rotation of a polishing cloth, and a pressing pressure of the polishing cloth in this time were set to be smaller than those in the conditions of the first mirror-surface chamfering process. Specifically, the second mirror-surface chamfering process was performed under the following conditions shown in Table 1. A mirror-surface chamfering process for the wafer edge portion, which was conventionally essential for the manufacturing process, was performed in this second mirror-surface chamfering process with the same mechanism under the same conditions as a conventional method.

TABLE 1

| | First mirror-surface | | | | Second mirror-surface | | | |
|---|---|---|---|---|---|---|---|---|
| | chamfering process | | | | chamfering process | | | |
| Example | 1st Stage | | 2nd Stage | | 1st Stage | | 2nd Stage | |
| Process time | 15 | seconds | 15 | seconds | 9 | seconds | 9 | seconds |
| Number of | 550 | rpm | 550 | rpm | 400 | rpm | 400 | rpm |
| rotation of | | | | | | | | |
| polishing cloth | | | | | | | | |
| Pressing | 0.6 | kgf/cm² | 0.7 | kgf/cm² | 0.4 | kgf/cm² | 0.6 | kgf/cm² |
| pressure of | | | | | | | | |
| polishing cloth | | | | | | | | |
| Polishing rate | 0.21 | μm/sec | 0.25 | μm/sec | 0.10 | μm/sec | 0.15 | μm/sec |

TABLE 2

| Common | Double-side polishing step | |
|---|---|---|
| Apparatus | DSP-20B, manufactured by | |
| | Fujikoshi Machinery Corp. | |
| Shore A hardness | 80 | |
| Polishing cloth | Polyurethane foam pad | |
| Slurry | Containing silica polishing | |
| | particles | |
| Average particle diameter | 35 | nm |
| Polishing particle | 2 | wt % |

| | |
|---|---|
| concentration | |
| pH | 11 |
| Base | KOH base |

Finally, the major surface of the wafer was subjected to a mirror polishing step.

After the mirror polishing step was finished, surface roughness of the wafer notch portion was measured. For the roughness measurement, LSM, manufactured by KOBELCO Research Institute, was used. The roughness is classified into macroscopic roughness and microscopic roughness therein, and the roughness in the present invention is presumed as the microscopic roughness. In analyzing the obtained measurement data, the macroscopic roughness component was removed to evaluate only the microscopic roughness component. There are also a plurality of evaluation criteria of the roughness, and in the present invention, total roughness in randomly selected regions was divided by an area of the selected regions, and the quotient was used as the criteria. Here, the randomly selected region indicated a region where the polishing sufficiently affected, and in evaluation with different wafers, regions with the same position and the same area were used to evaluate. The first and second slopes 21 and 22 and the end portion 23 illustrated in FIG. 4 in the bottom of the wafer notch portion were set to the evaluation region, and average roughness was calculated with each region in four wafers.

As a result of the roughness measurement, the surface roughness on the bottom of the wafer notch portion was 6.85 nm in the first slope 21, 9.42 nm in the second slope 22, and 4.26 nm in the end portion 23, as shown in FIG. 5 and the following Table 5.

### Comparative Example 1

In the same manner as in a conventional method for manufacturing a semiconductor wafer, each process of slicing, a chamfering step, wrapping, etching, double-side polishing major surfaces, a second mirror-surface chamfering process, and a mirror polishing step for the major surfaces was sequentially performed to obtain four wafers. That is, the mirror-surface chamfering process before the double-side polishing was not performed in the Comparative Example. In the mirror-surface chamfering step in the Comparative Example, the wafer notch portion was subjected to the mirror-surface chamfering process in order to achieve an amount of removal that was able to sufficiently remove scars, etc. and in order to manufacture the semiconductor wafer in the approximately same time as in Example. All of the process time, the number of rotation of the polishing cloth, and the pressing pressure of the polishing cloth were set to the conditions same as those in the first mirror-surface chamfering process in Example, as shown in the following Table 3. Each process of the slicing, the chamfering step, wrapping, and etching was performed under the same conditions as in Example. The double-side polishing of the major surface was also performed under the conditions shown in Table 2, which were the same as in Example 1.

With the four wafers obtained as above, roughness of the wafer notch portion was measured in the same manner as in Example to calculate the average roughness. The calculation method of the roughness from the obtained measurement data was same as in Example, and the above selected regions were also selected with the same position and the same area as those in Example.

TABLE 3

| | First mirror- | | | | |
|---|---|---|---|---|---|
| | surface | Second mirror-surface | | | |
| Comparative | chamfering | chamfering process | | | |
| Example 1 | process | 1st Stage | | 2nd Stage | |
| Process time | | 15 | seconds | 15 | seconds |
| Number of | | 550 | rpm | 550 | rpm |
| rotation of | | | | | |
| polishing cloth | | | | | |
| Pressing | | 0.6 | kgf/cm² | 0.7 | kgf/cm² |
| pressure of | | | | | |
| polishing cloth | | | | | |
| Polishing rate | | 0.21 | μm/sec | 0.25 | μm/sec |

### Comparative Example 2

In Comparative Example 2, four wafers were obtained in the same manner as in Example except that, as shown in the following Table 4, the conditions of the second mirror-surface chamfering process were same as the conditions of the first mirror-surface chamfering process. With the four wafers obtained as above, roughness of the wafer notch portion was measured in the same manner as in Example to calculate the average roughness. The calculation method of the roughness from the obtained measurement data was same as in Example, and the above selected regions were also selected with the same position and the same area as those in Example.

TABLE 4

| | First mirror-surface | | | | Second mirror-surface | | | |
|---|---|---|---|---|---|---|---|---|
| Comparative | chamfering process | | | | chamfering process | | | |
| Example 2 | 1st Stage | | 2nd Stage | | 1st Stage | | 2nd Stage | |
| Process time | 15 | seconds | 15 | seconds | 15 | seconds | 15 | seconds |
| Number of | 550 | rpm | 550 | rpm | 550 | rpm | 550 | rpm |
| rotation of | | | | | | | | |
| polishing cloth | | | | | | | | |
| Pressing | 0.6 | kgf/cm² | 0.7 | kgf/cm² | 0.6 | kgf/cm² | 0.7 | kgf/cm² |
| pressure of | | | | | | | | |
| polishing cloth | | | | | | | | |
| Polishing rate | 0.21 | μm/sec | 0.25 | μm/sec | 0.21 | μm/sec | 0.25 | μm/sec |

The following Table 5 shows the surface roughness of the first slope 21, the second slope 22, and the end portion 23, which are illustrated in FIG. 4, of the wafer notch portion in each of the wafers obtained in Example and Comparative Examples 1 and 2.

TABLE 5

| | First slope 21 | Second slope 22 | End portion 23 |
|---|---|---|---|
| Example | 6.85 | 9.42 | 4.26 |
| Comparative | 13.02 | 17.58 | 12.54 |
| Example 1 | | | |
| Comparative | 10.77 | 10.07 | 5.25 |
| Example 2 | | | |

The manufacturing process in Comparative Example 1, which had high polishing rate and load in the mirror-surface chamfering process performed after the double-side polishing of the major surface in the manufacturing process compared with Example, exhibited large roughness after the process (FIG. 5 and Table 5). As a result, the surface roughness of the wafer notch portion after the process in Comparative Example 1 were 13.02 nm in the first slope 21, 17.58 nm in the second slope 22, and 12.54 nm in the end portion 23, which are illustrated in FIG. 4, as shown in FIG. 5 and Table 5. All the surface roughness were higher than those in Example, and processing by the manufacturing process in Example was able to produce the wafer having improved surface roughness of the notch portion with keeping the productivity.

In the manufacturing process in Comparative Example 2, the conditions of the second mirror-surface chamfering process performed after the double-side polishing step of the major surface were same as the conditions of the first mirror-surface chamfering process performed before the double-side polishing step. As a result, the surface roughness of the wafer notch portion after the process in Comparative Example 2 were 10.77 nm in the first slope 21, 10.07 nm in the second slope 22, and 5.25 nm in the end portion 23, which were illustrated in FIG. 4, as shown in FIG. 5 and Table 5. All the surface roughness were higher than those in Example, and processing by the manufacturing processes in Example was able to produce the wafer having improved surface roughness of the notch portion.

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1.-4. (canceled)

5. A method for manufacturing a semiconductor wafer, comprising:
a chamfering step of grinding at least a periphery of a wafer having a wafer notch portion to form a chamfered portion having a wafer edge portion and the wafer notch portion;
a double-side polishing step of polishing both major surfaces of the wafer;
a mirror-surface chamfering step of polishing the chamfered portion to form a mirror surface; and
a mirror polishing step of mirror polishing at least one of both the major surfaces, wherein
the mirror-surface chamfering step comprises:
a first mirror-surface chamfering process of polishing the wafer notch portion in the chamfered portion before the double-side polishing step; and
a second mirror-surface chamfering process of polishing the wafer notch portion and the wafer edge portion after the double-side polishing step, and
a polishing rate of the wafer notch portion in the second mirror-surface chamfering process is smaller than a polishing rate of the wafer notch portion in the first mirror-surface chamfering process.

6. The method for manufacturing a semiconductor wafer according to claim 5, wherein the semiconductor wafer is a silicon wafer.

7. The method for manufacturing a semiconductor wafer according to claim 5, wherein in polishing the wafer notch portion in the first and second mirror-surface chamfering processes, the polishing is performed by inserting a circular polishing cloth into the wafer notch portion perpendicular to a wafer surface.

8. The method for manufacturing a semiconductor wafer according to claim 6, wherein in polishing the wafer notch portion in the first and second mirror-surface chamfering processes, the polishing is performed by inserting a circular polishing cloth into the wafer notch portion perpendicular to a wafer surface.

9. The method for manufacturing a semiconductor wafer according to claim 5, wherein
an end surface of the wafer notch portion has:
a first slope continued from one major surface of the wafer and inclined from the one major surface;
a second slope continued form the other major surface of the wafer and included from the other major surface; and
an end portion constituting an outermost periphery of the wafer, and
in the second mirror-surface chamfering process, all of the first slope, the second slope, and the end portion of the end surface of the wafer notch portion are polished.

10. The method for manufacturing a semiconductor wafer according to claim 6, wherein
an end surface of the wafer notch portion has:
a first slope continued from one major surface of the wafer and inclined from the one major surface;
a second slope continued form the other major surface of the wafer and included from the other major surface; and
an end portion constituting an outermost periphery of the wafer, and
in the second mirror-surface chamfering process, all of the first slope, the second slope, and the end portion of the end surface of the wafer notch portion are polished.

11. The method for manufacturing a semiconductor wafer according to claim 7, wherein
an end surface of the wafer notch portion has:
a first slope continued from one major surface of the wafer and inclined from the one major surface;
a second slope continued form the other major surface of the wafer and included from the other major surface; and
an end portion constituting an outermost periphery of the wafer, and
in the second mirror-surface chamfering process, all of the first slope, the second slope, and the end portion of the end surface of the wafer notch portion are polished.

12. The method for manufacturing a semiconductor wafer according to claim 8, wherein
an end surface of the wafer notch portion has:
a first slope continued from one major surface of the wafer and inclined from the one major surface;
a second slope continued form the other major surface of the wafer and included from the other major surface; and
an end portion constituting an outermost periphery of the wafer, and
in the second mirror-surface chamfering process, all of the first slope, the second slope, and the end portion of the end surface of the wafer notch portion are polished.
